(19) United States
(12) Patent Application Publication
(10) Pub. No.: US 2024/0407112 A1
(43) Pub. Date: Dec. 5, 2024

(54) DISPLAY DEVICE

(71) Applicant: SAMSUNG DISPLAY CO., LTD., YONGIN-SI (KR)

(72) Inventors: Sung Won KIM, YONGIN-SI (KR); Han Bum KWON, YONGIN-SI (KR)

(21) Appl. No.: 18/395,448

(22) Filed: Dec. 22, 2023

(30) Foreign Application Priority Data
Jun. 1, 2023 (KR) 10-2023-0071118

(51) Int. Cl. H05K 5/02; H05K 5/04

(52) U.S. Cl. CPC H05K 5/0217; H05K 5/04

(57) ABSTRACT

A display device includes: a display panel including a first area and a second area extending from the first area in a first direction, a first support plate disposed on a bottom of the display panel in the first area, a second support plate disposed on a bottom of the display panel in the second area, and a plurality of holes formed in the second support plate and extending substantially perpendicular to the first direction.

### CROSS-REFERENCE TO RELATED APPLICATION

This application claims priority under 35 U.S.C. § 119 to Korean Patent Application No. 10-2023-0071118, filed on Jun. 1, 2023, in the Korean Intellectual Property Office, the entire content of which are herein incorporated by reference.

### BACKGROUND

### 1. Technical Field

The present disclosure generally relates to a display device, and more particularly to a display device including a flexible display panel and a support plate.

### 2. Discussion of Related Art

In general, electronic devices that provide images to users include a display device for displaying an image. The display device may generate an image and provide the image to a user through a display screen. The display device may be, for example, a smartphone, a digital camera, a notebook computer, a navigation device, or a smart television.

Various types of display devices have been developed. For example, foldable or rollable display devices have been developed. These display devices may be easily and conveniently carried by a user.

### SUMMARY

Embodiments provide a display device having improved surface grade and durability while facilitating sliding of a display panel.

In accordance with an aspect of the present disclosure, there is provided a display device including: a display panel including a first area and a second area extending from the first area in a first direction; a first support plate disposed on a bottom of the display panel in the first area; a second support plate disposed on a bottom of the display panel in the second area; and a plurality of holes formed in the second support plate and extending substantially perpendicular to the first direction.

A shape of each of the plurality of holes may be any one of a circular shape, an elliptical shape, or a polygonal shape.

A diameter of each of the plurality of holes may be at least about 20 μm.

A distance between the plurality of holes may be at least about 0.3 μm.

A thickness of the second support plate may be about 200 to 300 μm.

The second support plate may include a metal material including at least one of titanium and aluminum.

The second support plate may further include a finishing member.

A modulus of the second support plate may be about 0.20 to 0.40 GPa.

The plurality of holes may include: a plurality of first holes formed at a side surface of an inside part of the second support plate with respect to a neutral plane of the second support plate; and a plurality of second holes formed at a side surface of an outside part of the second support plate with respect to the neutral plane.

The display device may further include a plurality of support bars disposed on the bottom of the second support plate; and a rotating member formed in an uneven structure to be engaged with the plurality of support bars.

The display device may further include: a first adhesive layer disposed on a rear surface of the display panel, the first adhesive layer overlapping with the first area and the second area; a protective film disposed on a rear surface of the first adhesive layer, the protective layer overlapping with the first area and the second area; a second adhesive layer disposed on a rear surface of the protective layer, the second adhesive layer overlapping with the first area; a third adhesive layer disposed on the rear surface of the protective layer, the third adhesive layer overlapping with the second area; a barrier layer disposed on a rear surface of the third adhesive layer, the barrier layer overlapping with the second area; and a fourth adhesive layer disposed on a rear surface of the barrier layer, the fourth adhesive layer overlapping with the second area. The first support plate may be disposed on a rear surface of the second adhesive layer, and the second support plate may be disposed on a rear surface of the fourth adhesive layer.

In accordance with another aspect of the present disclosure, there is provided a display device operating in a first display mode in which a display area is collapsed and a second display mode in which the display area is expanded, the display device including: a display panel including a first area and a second area extending from the first area; a first support plate disposed on a bottom of the display panel, the first support plate overlapping with the first area; a second support plate disposed on the bottom of the display panel, the second support plate overlapping with the second area; and a plurality of holes formed at a side surface of the second support plate.

An area of the second area exposed to an outside in the second display mode may be greater than the area of the second area exposed to the outside in the first display mode.

A shape of each of the plurality of holes may be any one of a circular shape, an elliptical shape, or a polygonal shape and a modulus of the second support plate may be about 0.20 to 0.40 GPa.

The plurality of holes may include: a plurality of first holes formed at a side surface of an inside part of the second support plate with respect to a neutral plane of the second support plate; and a plurality of second holes formed at a side surface of an outside part of the second support plate with respect to the neutral plane.

While the display mode of the display device is changed from the first display mode to the second display mode, at least some of the plurality of first holes may be contracted, and at least some of the plurality of second holes may be expanded.

The at least some of the plurality of first holes and the at least some of the plurality of second holes may correspond to a bending area of the second support plate.

The display device may further include: a plurality of support bars disposed on a bottom of the second support plate; and a rotating member may include a structure engaged with the plurality of support bars.

In accordance with another aspect of the present disclosure, there is provided a display device including: a display panel including a non-sliding area and a sliding area extending from the non-sliding area; a second support plate comprising at least three plates bounded together in a stack and disposed on a bottom of the display panel, the second support plate overlapping with the sliding area and including a flat shaped portion and a bent shaped portion; and a plurality of holes formed at a side surface of the second support plate, wherein the plurality of holes are disposed in at least two rows.

The display device may further include a first support plate disposed on the bottom of the display panel, the first support plate overlapping with the non-sliding area.

### BRIEF DESCRIPTION OF THE DRAWINGS

FIG. 1 is a perspective view of a display device in a first display mode in accordance with an embodiment of the present disclosure.

FIG. 2 is a perspective view of the display device in a second display mode in accordance with an embodiment of the present disclosure.

FIG. 3 is a sectional view of the display device taken along line I-I′ shown in FIG. 1.

FIG. 4 is a sectional view of the display device taken along line II-II′ shown in FIG. 2.

FIGS. 5 and 6 are views illustrating a second support plate and a plurality of holes in accordance with an embodiment of the present disclosure.

FIG. 7 is a view illustrating a manufacturing method of a second support plate in which a plurality of holes are formed in accordance with an embodiment of the present disclosure.

FIG. 8 is a view illustrating a method of forming a hole in a second support plate in accordance with an embodiment of the present disclosure.

### DETAILED DESCRIPTION

Example embodiments will now be described more fully hereinafter with reference to the accompanying drawings. However, the present disclosure is not limited to embodiments disclosed herein but may be implemented in various forms. Rather, embodiments are provided so that this disclosure will be thorough and complete, and will fully convey the scope of the present disclosure to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

The effects and characteristics of the present disclosure and a method of achieving the effects and characteristics will be clear by referring to embodiments described herein in detail together with the accompanying drawings. Embodiments are provided by way of example only so that a person of ordinary skilled in the art can fully understand the features in the present disclosure and the scope thereof. Therefore, the present disclosure can be defined by the scope of the appended claims.

The terminology used herein is for the purpose of describing aspects of the present disclosure and is not to be construed as limiting the inventive concept. As used herein, the singular forms are intended to include the plural forms as well, unless the context clearly indicates otherwise. The terms “comprises/includes” and/or “comprising/including,” when used in this specification, specify the presence of mentioned component, step, operation and/or element, but do not exclude the presence or addition of one or more other components, steps, operations and/or elements.

When any element is described as “connected”, “coupled” or “accessed” to another element, it should be understood that it is possible that still another element may be “connected”, “coupled” or “accessed” between the two elements as well as that the two elements are directly “connected”, “coupled” or “accessed” to each other.

The term “on” may be used to designate that an element or layer is on another element or layer includes both a case where the element or layer is located directly on another element or layer, and a case where the element or layer is located on another element or layer via still another element layer.

It will be understood that, although the terms “first,” “second,” etc. may be used herein to describe various elements, these elements should not be limited by these terms. These terms are only used to distinguish one element from another element. Thus, a “first” element discussed herein may also be termed a “second” element without departing from the teachings of the present disclosure.

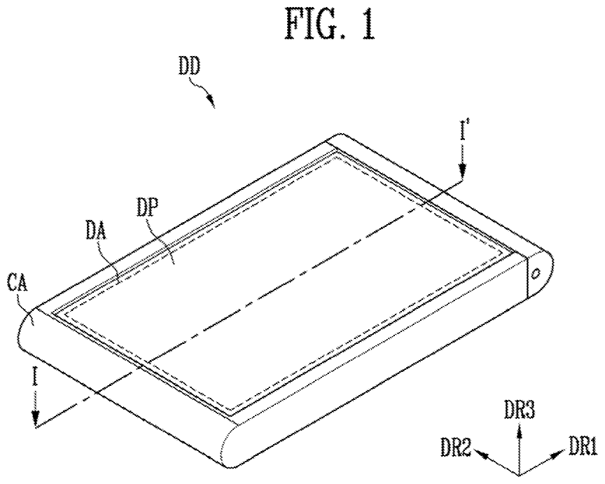

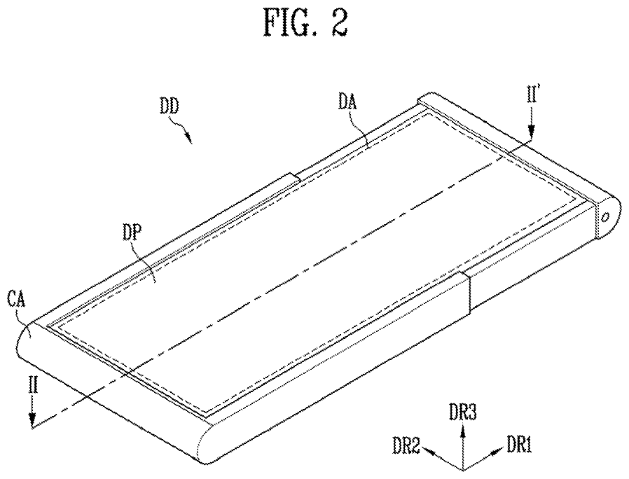

FIG. 1 is a perspective view of a display device DD in a first display mode in accordance with an embodiment of the present disclosure. FIG. 2 is a perspective view of the display device DD in a second display mode in accordance with an embodiment of the present disclosure.

Referring to FIG. 1 and FIG. 2, the display device DD may operate in different display modes. The first display mode means a mode in which an image is displayed in a state in which a display area DA of a display panel DP is relatively short. For example, the first display mode may mean a mode in which an image is displayed in a state in which a display area DA of a display panel DP is not expanded. The second display mode means a mode in which the image is displayed in a state in which the display area DA of the display panel DP is relatively long. For example, the second display mode may mean a mode in which an image is displayed in a state in which a display area DA of a display panel DP is expanded. An area of the display area DA may be greater in the second display mode than the first display mode. For example, an area of the display area DA that may be viewed by a user may be greater in the second display mode than the first display mode.

The display device DD may include the display panel DA and a case CA. The display panel DP may be a component which displays an image. The case CA may be a component which accommodates the display panel DP. For example, the case CA may partially accommodate the display panel and expose a portion of the display panel to an outside.

The display panel DP may be implemented as a flexible display panel. The flexible display panel refers to a flexible display panel that may be bent, curved, and/or rolled. The flexible display panel may be bent, curved, and/or rolled without loss of display characteristics. The flexible display panel may have features including lightness, thinness, and impact resistance. The flexible display panel may include a substrate made of a flexible material. For example, the flexible display panel may include a substrate formed of a polymer substance as a flexible material, such as polyimide or polyethylene terephthalate.

The display panel DP may include a light emitting display panel. For example, the light emitting display panel may be an organic light emitting display panel, an inorganic light emitting display panel, an organic-inorganic light emitting display panel, a quantum dot display panel, a micro LED display panel, or a nano LED display panel.

The display panel DP may display an image in the display area DA. Pixels for displaying the image may be disposed in the display area DA. For example, a plurality of the pixels may generate light forming the image.

An area of the display area DA exposed to the outside may be expanded as the case CA is extended. For example, when the display mode of the display device DD is changed from the first display mode to the second display mode the area of the display area DA exposed to the outside may be increased. When the area of the display area DA exposed to the outside is increased, the user may watch an image through a wider display area DA. For example, when the display mode of the display device DD is changed from the second display mode to the first display mode, the area of the display area DA may be reduced as the case CA is collapsed. As such, the area of the display area DA exposed to the outside can be controlled according to a state of the case CA. For example, the case CA may have an extended state or a collapsed state, but is not limited thereto, and the case CA may have an intermediate state.

The case CA may have at least a portion of the display panel DP mounted therein. For example, the case CA may have the display panel DP mounted thereto such that the display area DA of the display panel DP is an area exposed to the outside. The case CA may have the display panel DP mounted therein in various manners. For example, the case CA may have the display panel DP mounted therein in manners, such as roll-in, slide-in, band-in, or fold-in.

The case CA may include a plurality of portions that may be moved relative to each other. For example, the case CA may include a first portion and a second portion, and when the case CA is collapsed, the first portion and the second portion may be moved such that a length of the case CA may be reduced, and the area of the display area DA exposed to the outside may be decreased. When the case CA is extended, the first portion and the second portion may be moved such that the length of the case CA may be increased, and the area of the display area DA exposed to the outside may be increased.

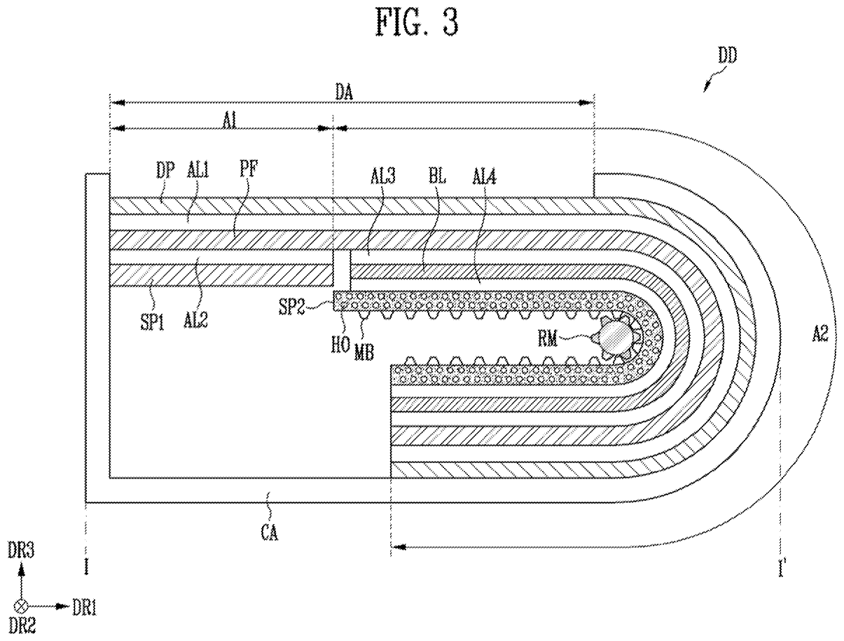

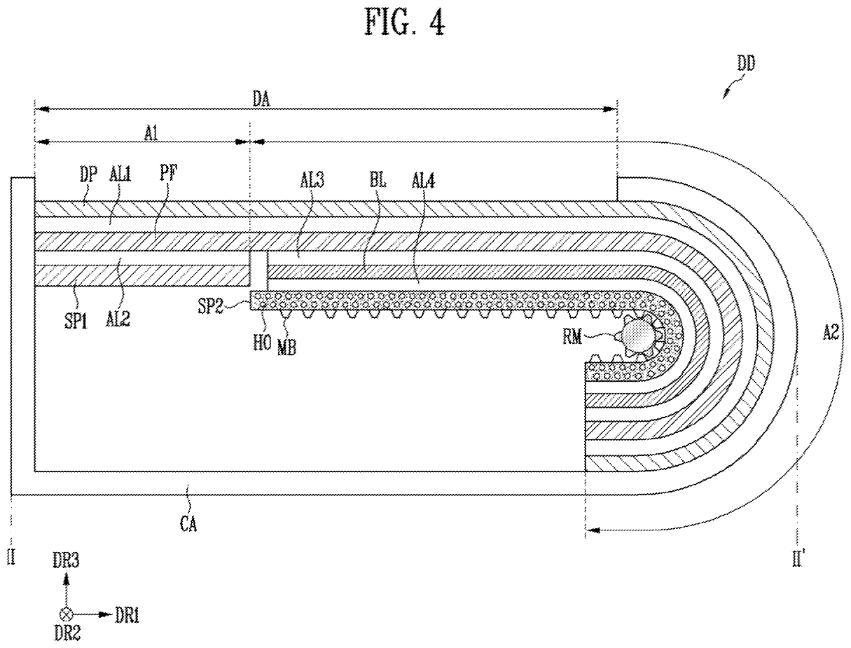

FIG. 3 is a sectional view of the display device DD taken along line I-I′ shown in FIG. 1. FIG. 4 is a sectional view of the display device DD taken along line II-II′ shown in FIG. 2.

Referring to FIG. 3 and FIG. 4, the display device DD may include the display panel DP, a first adhesive layer AL1, a protective film PF, a second adhesive layer AL2, a first support plate SP1, a third adhesive layer AL3, a barrier layer BL, a fourth adhesive layer AL4, a second support plate SP2, a plurality of support bars MB, and a rotating member RM.

The display panel DP may be disposed at a position overlapping with a first area A1 and a second area A2. The display panel DP may display an image in the display area DA including the first area A1 and at least a portion of the second area A2. The first area A1 and the at least a portion of the second area A2 may correspond to a display surface of the display panel DP exposed to the outside.

The first area A1 may be a non-sliding area overlapping with the first support plate SP1. The first area A1 exposed to the outside may have a same area in the first display mode and the second display mode.

The second area A2 may include a non-sliding area and a sliding area. The second area A2 may extend from the first area A1 and may overlap with the second support plate SP2. The second area A2 may extend from the first area A1 at a front portion of the case CA to a rear portion of the case CA. The front portion of the case CA may include a side of the display area DA and the rear portion of the case CA may include a side opposite to the display area DA. A portion of the second area A2 forming the display area DA may be included in the non-sliding area. The second area A2 may not include a non-sliding area, for example, when the case CA is in a collapsed state or when the second area A2 and the display area DA do not overlap. The portion of the second area A2 exposed to the outside may have different areas in the first display mode and the second display mode. For example, as a portion of the second support plate SP2 at the rear portion of the case CA is slid in the first direction DR1 and exposed at the front portion of the case CA, an area of the second area A2 exposed to the outside in the second display mode may be increased. The area of the second area A2 exposed to the outside in the second display mode may be greater than an area of the second area A2 exposed to the outside in the first display mode. The area of the display area DA may vary according to the area of the second area A2 exposed to the outside.

The first adhesive layer AL1 may be disposed at a position overlapping with the first area A1 and the second area A2. The first adhesive layer AL1 may be disposed on a rear surface of the display panel DA. An Optical Clear Adhesive (OCA) or a Pressure Sensitive Adhesive (PSA) may be disposed between the first adhesive layer AL1 and the display panel DA. For example, the first adhesive layer AL1 may include an adhesive member such as an Optical Clear Adhesive (OCA) or a Pressure Sensitive Adhesive (PSA).

The protective film PF may be disposed at a position overlapping with the first area A1 and the second area A2. The protective film PF may be disposed on a rear surface of the first adhesive layer AL1. The protective film PF may protect the display panel DP. The protective film PF may enable the display panel DP to be bent. The protective film PF may include a plastic material having flexibility. For example, the protective film PF may include polyimide (PI) or polyethylene terephthalate (PET).

The second adhesive layer AL2 may be disposed at a position overlapping with the first area A1. The second adhesive layer AL2 may be disposed between the protective film PF and the first support plate SP1 overlapping with the first area A1. The second adhesive layer AL2 may be disposed on a rear surface of the protective film PF overlapping with the first area A1. The second adhesive layer AL2 may include an adhesive member such as an Optical Clear Adhesive (OCA) or a Pressure Sensitive Adhesive (PSA).

The first support plate SP1 may be disposed at a position overlapping with the first area A1. The first support plate SP1 may be disposed on a rear surface of the second adhesive layer AL2 overlapping with the first area A1. The first support plate SP1 may have a flat shape. The first support plate SP1 and the second support plate SP2 may move independently along a sliding direction. For example, when the portion of the second support plate SP2 at the rear portion of the case CA is slid in the first direction DR1 (e.g., when the display mode of the display device DD is changed from the first display mode to the second display mode), the first support plate SP1 may move in an opposite direction of the first direction DR1. For example, the first support plate SP1 and the second support plate SP2 may be moved to be relatively apart, and the case CA may be extended. On the contrary, when the portion of the second support plate SP2 at the rear portion of the case CA is slid in the opposite direction of the first direction DR1 (e.g., when the display mode of the display device DD is changed from the second display mode to the first display mode), the first support plate SP1 may move in the first direction DR1. For example, the first support plate SP1 and the second support plate SP2 may be moved to be relatively together, and the case CA may be collapsed. A movement range of the first support plate SP1 may vary according to a sliding distance of the second support plate SP2.

The third adhesive layer AL3 may be disposed at a position overlapping with at least a portion of the second area A2. The third adhesive layer AL3 may be disposed on a rear surface of the protective film PF overlapping with the at least a portion of the second area A2. The third adhesive layer AL3 may be spaced apart from the second adhesive layer AL2 at a predetermined distance. For example, the third adhesive layer AL3 and the second adhesive layer AL2 may be disposed apart from each other. The third adhesive layer AL3 may include an adhesive member such as an Optical Clear Adhesive (OCA) or a Pressure Sensitive Adhesive (PSA).

The barrier layer BL may be disposed at a position overlapping with at least a portion of the second area A2. The barrier layer BL may be disposed at a rear surface of the third adhesive layer AL3 overlapping with at least a portion of the second area A2. The barrier layer BL may be disposed between the third adhesive layer AL3 and the fourth adhesive layer AL4. The barrier layer BL may be spaced apart from the first support plate SP1 at a predetermined distance. The barrier layer BL may protect the second support plate SP2. The barrier layer BL may enable the second support plate SP2 to be slid. The barrier layer BL may include polyimide (PI) or polyethylene terephthalate (PET).

The fourth adhesive layer AL4 may be disposed at a position overlapping with at least a portion of the second area A2. The fourth adhesive layer AL4 may be disposed on a rear surface of the barrier layer BL overlapping with at least a portion of the second area A2. The fourth adhesive layer AL4 may be spaced apart from the first support plate SP1 at a predetermined distance. The fourth adhesive layer AL4 may include an adhesive member such as an Optical Clear Adhesive (OCA) or a Pressure Sensitive Adhesive (PSA).

The second support plate SP2 may be disposed at a position overlapping with the second area A2. The second support plate SP2 may be disposed on a rear surface of the fourth adhesive layer AL4. The second support plate SP2 may have a flat shaped portion and a bent shaped portion. The bent shaped portion may be formed as the flat shaped portion is bent when the second support plate SP2 is slid. The bent shaped portion may be disposed between an exposed flat shaped portion at the front portion of the case CA and a concealed flat shaped portion at the rear portion of the case CA. In an example, as the case CA is collapsed, the concealed flat shaped portion may be slid in the opposite direction to the first direction DR1 relative to the exposed flat shaped portion, and an area of the exposed flat shaped portion may be decreased. In another example, as the case is expanded, the concealed flat shaped portion may be slid in the first direction DR1 relative to the exposed flat shaped portion, and an area of the exposed flat shaped portion may be increased.

When the display mode of the display device DD is changed from the first display mode to the second display mode, the concealed flat shaped portion of the second support plate SP2 at the rear portion of the case CA may be slid in the first direction DR1. On the contrary, when the display mode of the display device DD is changed from the second display mode to the first display mode, the concealed flat shaped portion of the second support plate SP2 at the rear portion of the case CA may be slid in the first direction DR1. As described herein, the area of the second area A2 exposed to the outside can be controlled according to a direction in which the second support plate SP2 is slid and a degree to which the second support plate SP2 is slid relative to the first support plate SP1.

The plurality of support bars MB may be disposed on a bottom of the second support plate SP2. For example, the plurality of support bars MB may be attached to the bottom of the second support plate SP2 through a thermocompression bonding process. The number of the plurality of support bars MB and the distance between adjacent support bars of the plurality of support bars MB are not particularly limited. The distance between adjacent support bars of the plurality of support bars MB may be set by considering the rotating member RM, sliding of the second support plate SP2, or the like. The plurality of support bars MB may be engaged with the rotating member RM, and accordingly, a portion of the second support plate SP2 at the rear portion of the case CA can be slid in the first direction DR1 or the opposite direction.

The rotating member RM may be disposed at an inside of the second support plate SP2. For example, the rotating member RM may be disposed at an inside of the bent shaped portion of the second support plate SP2. The rotating member RM may include a structure. The structure of the rotating member RM may engage with the plurality of support bars MB. In an example, the structure of the rotating member RM may include a plurality of cooperating bars that may engage with at least some of the plurality of support bars MB. As the rotating member RM rotates while the structure is engaged with the plurality of support bars MB, the second support plate SP2 can be slid.

The second support plate SP2 may be made of a material having a high rigidity. The second support plate SP2 may be made of a material supporting a stacked structure including the display panel DP. For example, the second support plate SP2 may be made of a metal material including at least one of titanium or aluminum.

The second support plate SP2 made of the metal material may have a high modulus (e.g., about 180 to 190 gigapascal (GPa)). The second support plate SP2 made of the metal material and may be formed to have a reduced modulus (e.g., less than about 180 to 190 GPa) such that the second support plate SP2 may be slid and bent around the rotating member RM.

In an example, holes may be formed in the second support plate SP2, thereby reducing the modulus of the second support plate SP2. For example, holes having a lattice structure may be formed at a top surface of the second support plate SP2, thereby reducing the modulus of the second support plate SP2. The modulus of the second support plate SP2 may be decreased (e.g., to about 0.30 to 0.40 GPa) due to the holes having the lattice structure, which may be formed at the top surface of the second support plate SP2.

The display device DD in accordance with an embodiment of the present disclosure may include a plurality of holes HO formed at a side surface of the second support plate SP2 (see FIG. 3 and FIG. 4). In an example, the plurality of holes HO extend substantially perpendicular to the first direction DR1. Since the plurality of holes HO are formed at the side surface, external visibility of the holes may be low, and a surface grade of the display device DD can be improved.

In an example in which the plurality of holes HO are formed at the side surface of the second support plate SP2, the modulus of the second support plate SP2 may be decreased. In an embodiment, the modulus of the second support plate SP2 may be about 0.20 to 0.40 GPa. In an example in which the second plate SP2 have a modulus of about 0.20 to 0.40 GPa, the second support plate SP2 may be slid and moved around the rotating member RM. Further, an impact resistance of the second support plate SP2 may be ensured. In an example in which the second plate SP2 have a modulus of about 0.20 to 0.40 GPa, the second support plate SP2 may be prevented drooped or modified in the sliding thereof.

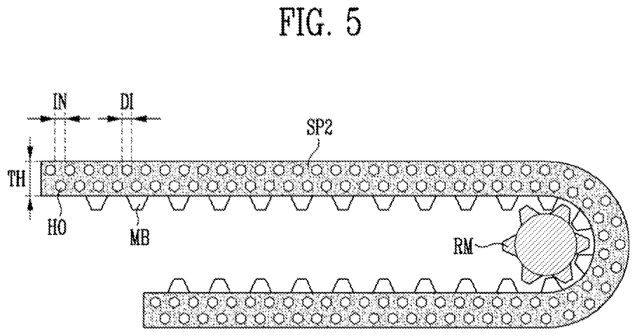

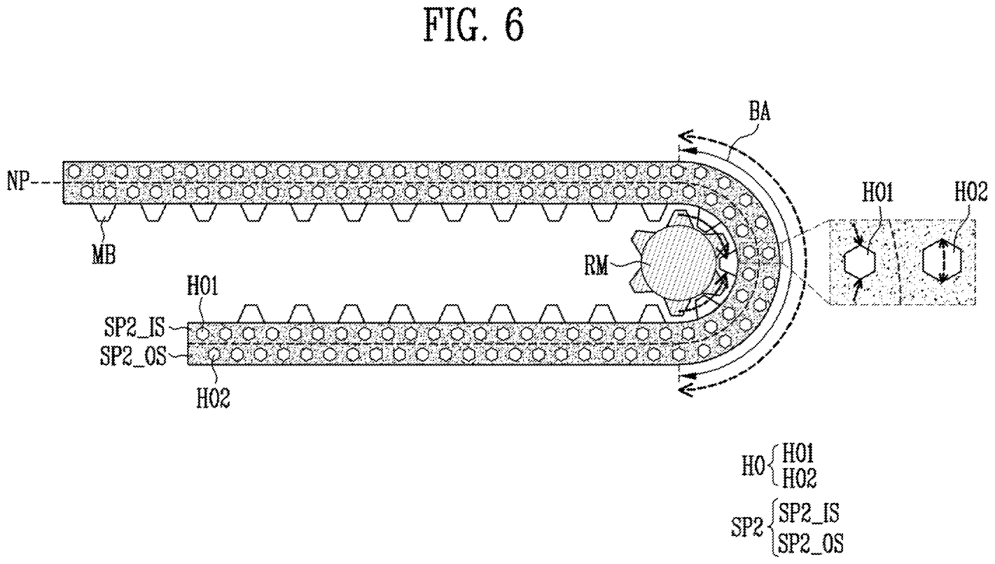

FIG. 5 and FIG. 6 are views illustrating a second support plate SP2 and a plurality of holes HO in accordance with an embodiment of the present disclosure.

Referring to FIG. 5, in an embodiment, a thickness TH of the second support plate SP2 may be about 200 to 300 micrometers (μm). The second support plate SP2 having the thickness TH of about 200 to 300 μm may stably support the stacked structure including the display panel DP. In addition, a sufficient space for forming the plurality of holes HO at the side surface of the second support plate SP2 can be secured.

In an embodiment, a shape of each of the plurality of holes HO may be any one of a circular shape, an elliptical shape, or a polygonal shape. For example, the shape of each of the plurality of holes HO may be a hexagonal shape. In addition, when the shape of each of the plurality of holes HO is the hexagonal shape, the plurality of holes HO may be formed in a honeycomb structure. Hereinafter, for convenience of description, a case where the shape of each of the plurality of holes HO is the hexagonal shape will be mainly described. However, embodiments of the present disclosure are not limited. For example, some of the plurality of holes HO may have the same shape, and some of the plurality of holes HO may have different shapes. Each of the plurality of holes HO may have various shapes such as a triangular shape or a quadrangular shape.

In an embodiment, a diameter DI of each of the plurality of holes HO may be at least about 20 μm. In an embodiment, a distance IN between the plurality of holes HO may be at least about 0.3 μm. Accordingly, the modulus and impact resistance of the second support plate SP2 may enable the sliding of the second support plate SP2, which is caused by the rotating member RM and the plurality of support bars MB, and the sliding may be stably and easily performed. For example, the sliding of the second support plate SP2 may include moving a portion of the second support plate SP2 around the rotating member RM.

Referring to FIG. 6, the second support plate SP2 may include an inside part SP2_IS and an outside part SP2_OS, which may be divided with respect to a neutral plane NP.

The neutral plane NP may be an area which maintains an original shape without being contracted or expanded when the second support part SP2 is slid. For example, the neutral plane NP may be an area which maintains an original shape without being contracted or expanded when the second support part SP2 is slid and a portion of the second support plate SP2 is moved around the rotating member RM.

The inside part SP2_IS of the second support plate SP2 may be an area which may be contracted when the second support part SP2 is slid from the flat shaped portion to the bent shaped portion around the rotating member RM. When the second support part SP2 is slid from the flat shaped portion to the bent shaped portion around the rotating member RM, the inside part SP2_IS of the second support plate SP2 may be contracted, and a phenomenon (or buckling) in which the second support plate SP2 may be buckled may be reduced or prevented.

The outside part SP2_OS of the second support plate SP2 may be an area which may be expanded when the second support part SP2 is slid from the flat shaped portion to the bent shaped portion around the rotating member RM. When the second support part SP2 is slid from the flat shaped portion to the bent shaped portion around the rotating member RM, the outside part SP2_OS of the second support plate SP2 may be expanded, and a phenomenon (or tearing) in which the second support plate SP2 may be torn can be reduced or prevented.

The plurality of holes HO may include a plurality of first holes HO1 and a plurality of second holes HO2. The plurality of first holes HO1 may be formed at a side surface of the inside part SP2_IS of the second support plate SP2. The plurality of second holes HO22 may be formed at a side surface of the outside part SP2_OS of the second support plate SP2.

In an embodiment, while the display mode of the display device DD is changed from the first display mode to the second display mode or from the second display mode to the first display mode, at least some of the plurality of first holes HO1 may be contracted, and at least some of the plurality of second holes HO2 may be expanded. For example, when the second support plate SP2 is slid, first holes HO1 corresponding to a bending area BA of the second support plate SP2 among the plurality of first holes HO1 may be contracted, and a size of the first holes HO1 may be decreased. In addition, when the second support plate SP2 is slid, second holes HO2 corresponding to the bending area BA of the second support plate SP2 among the plurality of second holes HO2 may be expanded, and a size of the second holes HO1 may be increased. As a result, residual stress in the second support plate SP2 may be distributed, and a fatigue phenomenon may be reduced or prevented. For example, the fatigue phenomenon may include the second support plate SP2 breaking due to wear accumulated during repeated sliding.

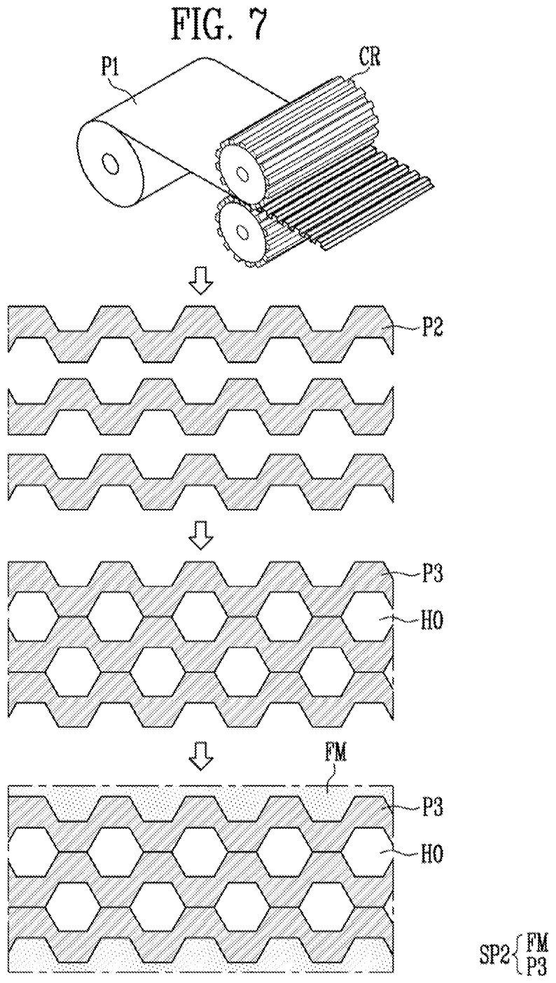

FIG. 7 is a view illustrating a manufacturing method of a second support plate SP2 in accordance with an embodiment of the present disclosure. In an example, the manufacturing method of a second support plate SP2, a plurality of holes HO may be formed.

Referring to FIG. 7, a first plate P1 may be made to pass through a corrugating roller CR, thereby machining the first plate P1 into a second plate P2 having semi-hexagonal shapes. A plurality of second plates P2 may be attached to each other. For example, the plurality of second plates P2 may be attached to each other in a stack through thermocompression bonding, thereby machining the plurality of second plates P2 into a third plate P3 in which a plurality of holes HO are formed. The plurality of holes HO may be disposed in at least two rows stacked in the third direction DR3.

The plurality of holes HO may extend substantially perpendicular to the first direction DR1. The plurality of holes HO may extend entirely across the third plate p3 and may be visible at a side surface of the third plate P3. In an example, a hole of the plurality of holes HO may include a plurality of discontinuous portions extending in a line substantially perpendicular to the first direction DR1. In an example, the plurality of holes HO may extend across a portion of the third plate P3, and the plurality of holes HO may not be visible at the side surface of the third plate P3.

In FIG. 7, it is illustrated that three second plates P2 are attached to each other. However, the present disclosure is not limited thereto, and the number of second plates P2 to be attached may increase according to the number of holes HO to be formed. A finishing member FM may be attached to a top and a bottom of the third plate P3, thereby manufacturing a second support plate SP2 in which a plurality of holes HO are formed. For example, the finishing member FM may include a film made of synthetic resin or a substance such as a material constituting the third plate P3.

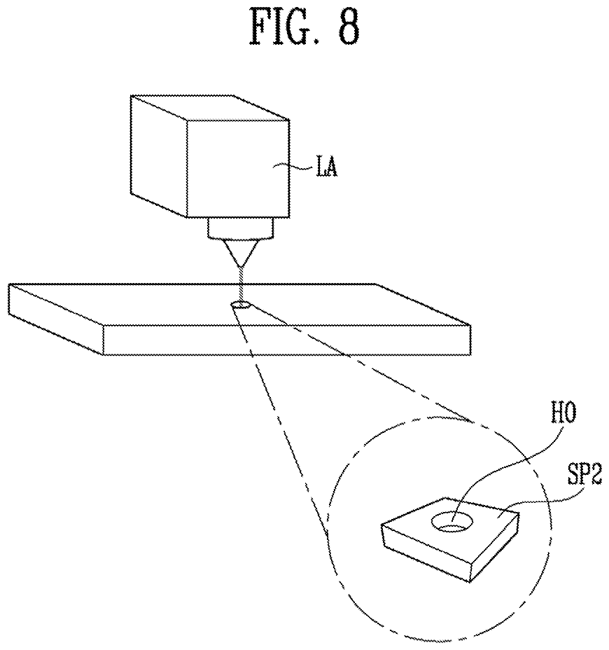

FIG. 8 is a view illustrating a method of forming a hole HO in a second support plate SP2 in accordance with an embodiment of the present disclosure.

Referring to FIG. 8, a hole HO may be formed in a second support plate SP2 by using a laser LA. A laser beam may be irradiated from the laser LA and may apply heat to the second support plate SP2, thereby forming the hole HO. In an example, the laser LA may be femtosecond later. When the laser LA is used, holes HO having various shapes such as a circular shape, an elliptical shape, or a polygonal shape can be formed. In addition, holes HO having a fine size can be machined with a constant arrangement. As a distance between the holes HO is reduced, the number of holes HO formed in the second support plate SP2 may be increased.

In accordance with the present disclosure, a display device including sliding of a display panel may have an improved surface grade and durability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a display panel including a first area and a second area extending from the first area in a first direction;
a first support plate disposed on a bottom of the display panel in the first area;
a second support plate disposed on the bottom of the display panel in the second area; and
a plurality of holes formed in the second support plate and extending substantially perpendicular to the first direction.

2. The display device of claim 1, wherein a shape of each of the plurality of holes is any one of a circular shape, an elliptical shape, or a polygonal shape.

3. The display device of claim 1, wherein a diameter of each of the plurality of holes is at least about 20 micrometers.

4. The display device of claim 1, wherein a distance between adjacent ones of the plurality of holes is at least about 0.3 micrometers.

5. The display device of claim 1, wherein a thickness of the second support plate is about 200 to 300 micrometers.

6. The display device of claim 1, wherein the second support plate includes a metal material including at least one of titanium and aluminum.

7. The display device of claim 1, wherein the second support plate further includes a finishing member.

8. The display device of claim 1, wherein a modulus of the second support plate is about 0.20 to 0.40 gigapascal.

9. The display device of claim 1, wherein the plurality of holes include:
a plurality of first holes formed at a side surface of an inside part of the second support plate with respect to a neutral plane of the second support plate; and
a plurality of second holes formed at a side surface of an outside part of the second support plate with respect to the neutral plane.

10. The display device of claim 1, further comprising:
a plurality of support bars disposed on a bottom of the second support plate; and
a rotating member having a structure engaged with at least some of the plurality of support bars.

11. The display device of claim 1, further comprising:
a first adhesive layer disposed on a rear surface of the display panel, the first adhesive layer overlapping with the first area and the second area;
a protective film disposed on a rear surface of the first adhesive layer, the protective film overlapping with the first area and the second area;
a second adhesive layer disposed on a rear surface of the protective film, the second adhesive layer overlapping with the first area;
a third adhesive layer disposed on the rear surface of the protective film, the third adhesive layer overlapping with the second area;
a barrier layer disposed on a rear surface of the third adhesive layer, the barrier layer overlapping with the second area; and
a fourth adhesive layer disposed on a rear surface of the barrier layer, the fourth adhesive layer overlapping with the second area,
wherein the first support plate is disposed on a rear surface of the second adhesive layer, and
the second support plate is disposed on a rear surface of the fourth adhesive layer.

12. A display device operating in a first display mode in which a display area is collapsed and a second display mode in which the display area is expanded, the display device comprising:
a display panel including a first area and a second area extending from the first area;
a first support plate disposed on a bottom of the display panel, the first support plate overlapping with the first area;
a second support plate disposed on the bottom of the display panel, the second support plate overlapping with the second area; and
a plurality of holes formed at a side surface of the second support plate.

13. The display device of claim 12, wherein an area of the second area exposed to an outside in the second display mode is greater than the area of the second area exposed to the outside in the first display mode.

14. The display device of claim 12, wherein a shape of each of the plurality of holes is any one of a circular shape, an elliptical shape, or a polygonal shape, and a modulus of the second support plate in which the plurality of holes are formed is about 0.20 to 0.40 gigapascal.

15. The display device of claim 12, wherein the plurality of holes include:
a plurality of first holes formed at a side surface of an inside part of the second support plate with respect to a neutral plane of the second support plate; and
a plurality of second holes formed at a side surface of an outside part of the second support plate with respect to the neutral plane.

16. The display device of claim 15, wherein, while a display mode of the display device is changed from the first display mode to the second display mode, at least some of the plurality of first holes are contracted, and at least some of the plurality of second holes are expanded.

17. The display device of claim 16, wherein the at least some of the plurality of first holes and the at least some of the plurality of second holes correspond to a bending area of the second support plate.

18. The display device of claim 12, further comprising:
a plurality of support bars disposed on a bottom of the second support plate; and
a rotating member includes a structure engaged with at least some of the plurality of support bars.

19. A display device comprising:
a display panel including a non-sliding area and a sliding area extending from the non-sliding area;
a second support plate comprising at least three plates bounded together in a stack and disposed on a bottom of the display panel, the second support plate overlapping with the sliding area and including a flat shaped portion and a bent shaped portion; and
a plurality of holes formed at a side surface of the second support plate, wherein the plurality of holes are disposed in at least two rows.

20. The display device of claim 19, further comprising a first support plate disposed on the bottom of the display panel, the first support plate overlapping with the non-sliding area.
